(19) United States
(12) Patent Application Publication
(10) Pub. No.: US 2024/0087981 A1
(43) Pub. Date: Mar. 14, 2024

(54) HEAT SINK FOR A SEMICONDUCTOR SWITCHING DEVICE, AND SEMICONDUCTOR SWITCHING DEVICE

(71) Applicant: Siemens Aktiengesellschaft, München (DE)

(72) Inventor: Walter Apfelbacher, Freihung (DE)

(21) Appl. No.: 18/465,303

(22) Filed: Sep. 12, 2023

(30) Foreign Application Priority Data
Sep. 12, 2022 (DE) 10 2022 209 492.1

(51) Int. Cl. H01L 23/40

(52) U.S. Cl. CPC H01L 23/4006; H01L 23/4093; H01L 2023/4018; H01L 2023/4087

(57) ABSTRACT

A heat sink for a semiconductor switching device. The heat sink has a contact surface for producing planar contact with one or more elements of a power module of the semiconductor switching device that are to be cooled. The heat sink additionally has measures for positioning the power module on and fastening it to the heat sink in a preferred position, and a fastening plate with molded-on mountings for positioning and mounting the heat sink on a carrier device. The heat sink, including the contact surface and the fastening plate, is manufactured in one piece from electrically insulating, thermally conductive plastics material having a thermal conductivity of at least 2 W/(m·K).

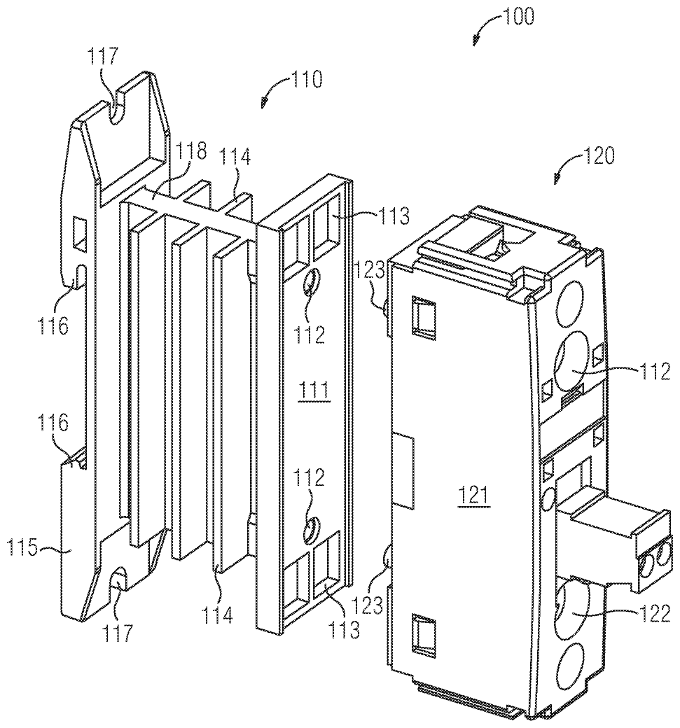

### CROSS-REFERENCE TO RELATED APPLICATION

This application claims the priority, under 35 U.S.C. § 119, of German Patent Application DE 10 2022 209 492.1, filed Sep. 12, 2022; the prior application is herewith incorporated by reference in its entirety.

### FIELD AND BACKGROUND OF THE INVENTION

The present invention relates to an improved heat sink for a semiconductor switching device, and to an improved semiconductor switching device.

It is generally known to mount assemblies, for example semiconductor switching devices, in switch cabinets on so-called top hat rails. The top hat rails are generally attached to the rear wall or to a frame of a switch cabinet. To this end, the assembly has a top hat rail fastening or a top hat rail adapter, which allows the assembly to be mounted on the two legs of the top hat rail, which lie in a plane. In addition, locking devices are in most cases provided, by means of which the assembly can be removed from the top hat rail again in a simple operation.

In semiconductor switching devices, heat develops owing to the voltage drop across the semiconductor switch(es) and the current flowing through it/them and in conventional semiconductor switching devices is dissipated by way of metallic heat sinks. In order that the semiconductor switching devices can be mounted on the top hat rails, the heat sinks are connected to the above-mentioned top hat rail fastenings or top hat rail adapters.

It is a disadvantage here that the adapter generally consists of a plurality of individual parts and must be fastened to the heat sink. Moreover, the heat sink must be grounded, and for this reason mounting of the semiconductor switching device on the top hat rail requires multiple steps and is correspondingly complicated and cost-intensive.

In order to avoid this disadvantage published, non-prosecuted German patent application DE 10 2012 112 393 A1 proposes equipping a heat sink for cooling an electrical component with a contact surface which can be brought into thermally conductive contact with a counter contact surface of the electrical component. The contact surface has at least one elastically deformable section and wherein the heat sink can be manufactured in one piece from a single fiber-reinforced plastics material.

International patent disclosure WO 2021/037854 A1 discloses a plastics housing for an electronic device consisting of a polymer, wherein a thermoplastic having a thermal conductivity of 3 W/(m·K) is used.

Published, non-prosecuted German patent application DE 101 48 623 A1, corresponding to U.S. patent publication No. 2005/0006053, discloses a device for fixing a profile part to a bearer rail having an adapter-like discrete connecting element which has first fixing means, which are able to be connected to the profile part, and second fixing means, which are able to be connected to the bearer rail. The connecting element can have at least one fixing opening which, by means of conventional screws, rivets or the like, can be used as an alternative to the second fixing means in conjunction with the bearer rail.

### SUMMARY OF THE INVENTION

The object of the present invention is to provide a further improved heat sink and an improved semiconductor switching device.

With the foregoing and other objects in view there is provided, in accordance with the invention, a heat sink for a semiconductor switching device. The heat sink contains: a contact surface for producing planar contact with at least one element of a power module of the semiconductor switching device that is to be cooled; means for positioning the power module on and fastening it to the heat sink in a given position, the means configured to produce a snap connection between the power module and the heat sink; and a fastening plate having a molded-on means for positioning and mounting the heat sink on a carrier device. The heat sink, including the contact surface and the fastening plate, are manufactured in one piece from an electrically insulating, thermally conductive plastics material having a thermal conductivity of at least 2 W/(m·K).

This object is achieved by a heat sink having the features of the independent patent claim. In particular, the heat sink is manufactured in one piece from electrically insulating but thermally conductive plastics material and has both means for fastening the power module to the heat sink and means for fastening the heat sink, or the semiconductor switching device formed of the heat sink and the power module, to a carrier device, in particular to a top hat rail. The means for fastening the power module to the heat sink are configured to produce a snap connection between the power module and the heat sink.

Compared to conventional semiconductor switching devices, an important advantage consists in that the one-piece plastics heat sink incorporates the top hat rail adapter, for example, and a separate adapter and the mentioned large number of individual parts and mounting steps are thus avoided. Moreover, the heat sink according to the invention does not have to be grounded, because the heat sink is produced from electrically non-conductive material.

In accordance with a feature of the invention, the means for positioning the power module on and fastening it to the heat sink in the given position has a fastening hole for receiving pins or screws or bolts of the power module.

In accordance with an added feature of the invention, the molded-on means for positioning and mounting the heat sink is configured for mounting the heat sink on a top hat rail.

In accordance with another feature of the invention, the molded-on means for positioning and mounting the heat sink is configured to produce a snap connection between the heat sink and the top hat rail.

In accordance with a further feature of the invention, the molded-on means for positioning and mounting the heat sink has screw fastening contours.

With the foregoing and other objects in view there is provided, in accordance with the invention a semiconductor switching device having a power module and the heat sink as described above.

Other features which are considered as characteristic for the invention are set forth in the appended claims.

Although the invention is illustrated and described herein as embodied in a heat sink for a semiconductor switching device, and a semiconductor switching device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURE OF THE DRAWING

The FIGURE of the drawing is an exploded, perspective view of a semiconductor switching device.

### DETAILED DESCRIPTION OF THE INVENTION

Turning now to the single FIGURE of the drawing, there is shown, in a schematic representation, an exemplary embodiment of the invention in which a plastics heat sink 110 and a power module 120 form a semiconductor switching device 100, wherein the heat sink 110 and the power module 120 are shown in the state in which they are not mounted to one another.

The heat sink has on the power module side a planar region 111, which is provided to contact in a planar manner one or more elements (not shown) of the power module that are to be cooled. The elements to be cooled preferably have corresponding planar regions, in order to achieve optimal heat transfer between the elements to be cooled and the heat sink. Suitable means for transporting heat from the actual heat source to the rear surface of the power module, such as, for example, heat sinks, heat spreaders or heat pipes which can be attached to semiconductor components, are well known to a person skilled in the art.

In order to further improve the transfer of heat between the elements to be cooled and the heat sink, additional measures can be taken prior to mounting, such as, for example, the application of thermally conductive paste or the attachment of thermally conductive pads (not shown) to the planar region 111.

The heat sink additionally has on the power module side means for positioning the power module on and fastening it to the heat sink, which means are configured to produce a snap connection between the power module and the heat sink. Purely by way of example, additional means for positioning and fastening in the form of two fastening holes 112 for receiving pins and/or screws or bolts 122, 123 of the power module are shown. For better positioning there can be provided, for example, pins which fit the holes 112 in a form-fitting manner and through which the screws or bolts can then be fastened with receiving means positioned in the holes 112.

In addition or alternatively, the fastening plate can be provided on the power module side with shaped elements 113 (recesses in the example of the FIGURE) which are configured to match corresponding shaped elements on the side of the power module that faces the heat sink in the mounted state and, together therewith, effect precise positioning of the power module on the heat sink and a more stable connection between the two elements, for example in combination with a defined contact pressure, which is produced by the bolts/screws 122, 123, which preferably extend through the housing 121 of the power module and are screwed in the heat sink from the front side of the power module with a corresponding tightening torque.

The heat sink 110 preferably has a plurality of cooling fins 114 or other elements which increase the surface area, in order to facilitate heat dissipation from the heat sink to the surrounding medium, in most cases the surrounding air. In the exemplary embodiment shown, the heat sink 110 has a linear core 118, which extends between the fastening plate on the power module side and a fastening plate 115 arranged substantially parallel thereto. The core 118 has on the one hand the purpose of transporting heat away from the fastening plate on the power module side to the cooling fins 114 and on the other hand the purpose of ensuring the mechanical stability of the semiconductor switching device 100, in particular when the semiconductor switching device is mounted in the operative state by the fastening plate 115 on a carrier device, for example a switch cabinet.

The fastening plate 115 on the carrier device side is formed in one piece with the heat sink 110 and is used for mounting the heat sink, or the semiconductor switching device as a whole, on a carrier device, for example a carrier rail, a wall or a panel, for example inside a switch cabinet or switch box.

In a preferred embodiment, the fastening plate has on the rear side mounting means 116 which are configured for the positioning and direct, that is to say adapter-free, mounting of the heat sink on a top hat rail, in particular on a top hat rail in accordance with EN 50022. The mounting means 116 can be configured to produce a snap connection between the heat sink 110 and the top hat rail, wherein the snap connection can be designed to be detachable.

Alternatively or in addition to the snap connection between the carrier device and the heat sink, a screw connection can be provided between the carrier device and the heat sink. Accordingly, as an alternative or in addition to the fastening means 116 with a top hat rail contour, screw fastening contours 117, in the example of the FIGURE screw or bolt receiving holes which are open on one side, are formed in the fastening plate 115.

In the pre-mounted state (not shown), the power module 120 is mechanically fixedly connected to the heat sink 110 and thus forms the finished semiconductor switching device 100, which can then be fastened to the carrier device provided, for example a top hat rail, without additional adapters or other mounting aids. The connection between the power module and the heat sink is preferably made, as already mentioned, by means of at least two screw fittings 123 through the housing 121 of the power module 120, wherein the contact pressure produced by the screw/bolt heads in the recesses 122 in the housing is distributed within the power module such that on the one hand secure fastening of the power module to the heat sink in accordance with a preferred position is achieved and on the other hand a good thermal connection between the elements to be cooled, which are arranged on the rear side of the power module on the heat sink side, and the heat sink is achieved.

In the exemplary embodiment shown in the FIGURE, a heat sink having a total of six cooling fins has been shown. Depending on the thermal conductivity of the plastics material used, which according to the invention is at least 2 W/(m·K), and on the nature of the flow of medium around the heat sink, fewer cooling ribs can be provided for the same cooling efficiency. For a greater cooling efficiency, correspondingly more cooling fins can be provided.

The present invention is suitable in particular for low-voltage switching devices with a switching voltage of up to 1000 V, that is to say, for example, for switching devices for conventional domestic voltages of 230 V with respect to the neutral line or 400 V between the individual phases.

An example of a heat sink in this voltage range can have six cooling fins (three pairs) for switching devices having a rated current of 10 A and fourteen cooling fins (seven pairs) for switching devices having a rated current of 30 A.

It should be pointed out that, in the drawing and in the above text, the terms, or the spatial orientation, “top”, “bottom”, “horizontal”, “vertical”, “front”, “rear” should not be interpreted as being limiting.

It should further be pointed out that the various exemplary embodiments described here can be combined with one another without limitation.

1. A heat sink for a semiconductor switching device, the heat sink comprising:
a contact surface for producing planar contact with at least one element of a power module of the semiconductor switching device that is to be cooled;
means for positioning the power module on and fastening it to the heat sink in a given position, said means configured to produce a snap connection between the power module and the heat sink;
a fastening plate having a molded-on means for positioning and mounting the heat sink on a carrier device; and
the heat sink, including said contact surface and said fastening plate, being manufactured in one piece from an electrically insulating, thermally conductive plastics material having a thermal conductivity of at least 2 W/(m·K).

2. The heat sink according to claim 1, wherein said means for positioning the power module on and fastening it to the heat sink in the given position has a fastening hole formed therein for receiving pins or screws or bolts of the power module.

3. The heat sink according to claim 1, wherein said molded-on means for positioning and mounting the heat sink is configured for mounting the heat sink on a top hat rail.

4. The heat sink according to claim 3, wherein said molded-on means for positioning and mounting the heat sink is configured to produce a snap connection between the heat sink and the top hat rail.

5. The heat sink according to claim 1, wherein the molded-on means for positioning and mounting the heat sink has screw fastening contours.

6. A semiconductor switching device, comprising:
a power module; and
the heat sink according to claim 1.
